(19) United States
(12) Patent Application Publication
(10) Pub. No.: US 2025/0079803 A1
(43) Pub. Date: Mar. 6, 2025

(54) SEMICONDUCTOR DEVICE AND METHOD FOR MANUFACTURING SAME

(71) Applicant: Mitsubishi Electric Corporation, Tokyo (JP)

(72) Inventor: Hiroyuki KAWAHARA, Tokyo (JP)

(73) Assignee: Mitsubishi Electric Corporation, Tokyo (JP)

(21) Appl. No.: 18/726,447

(22) PCT Filed: Mar. 17, 2022
(86) PCT No.: PCT/JP2022/012244

§ 371 Date: Jul. 3, 2024

(51) Int. Cl. H01S 5/227; H01S 5/30

(52) U.S. Cl. CPC H01S 5/2275; H01S 5/3013

(57) ABSTRACT

A semiconductor device of the present disclosure includes: an InP semiconductor substrate; stacked semiconductor layers formed on the semiconductor substrate and including a first-conductivity-type first semiconductor layer, an undoped active layer, and a second-conductivity-type semiconductor layer; a first-conductivity-type second semiconductor layer formed on the stacked semiconductor layers; and an insulating film formed in contact with the first-conductivity-type second semiconductor layer, wherein the insulating film has an opening at the bottom thereof so as to expose the first-conductivity-type second layer.

### TECHNICAL FIELD

The present disclosure relates to a semiconductor device and a method for manufacturing the same.

### BACKGROUND ART

InP-based semiconductor lasers used for optical communication applications require a broadband modulation frequency for individual devices in order to accommodate increasing capacity of communications. In addition, to reduce power consumption of the entire optical communication system, an increase in the light emission efficiency of the individual devices is required. The device resistance of a semiconductor device has a significant effect on both frequency bandwidth and the light emission efficiency. Mobility of holes is smaller than that of electrons, and thus the resistance of a p-type semiconductor layer occupies a large proportion of the device resistance of semiconductor layers with respect to the resistances of the overall semiconductor layers.

In consideration of the above-mentioned factors, n-type semiconductor substrates are generally used in the InP-based semiconductor lasers for optical communications in order to adapt n-type semiconductor layers with low resistance to the long current paths. That is, the n-type semiconductor substrate is located on the back surface side of the semiconductor device, and the p-type semiconductor layer is located on the front surface side of the semiconductor device.

### CITATION LIST

### Non-Patent Document

Non-Patent Document 1: J. Chevallier, A. Jalil, B. Theys, J. C. Pesant, M. Aucouturier, B. Rose and A. Mircea, “Hydrogen passivation of shallow acceptors in p-type InP”, Semicond. Sci. Technol. 4 (1989) pp. 87-90
Non-Patent Document 2: Hiroshi Ito, Shoji Yamahata, Naoteru Shigekawa and Kenji Kurishima, “Heavily Carbon Doped Base InP/InGaAs Heterojunction Bipolar Transistors Grown by Two-step Metalorganic Chemical Vapor Deposition”, Jpn. J. Appl. Phys., vol. 35 (1996) pp. 6139 to 6144

### SUMMARY OF THE INVENTION

### Problems to be Solved by the Invention

As described above, the InP-based semiconductor laser for optical communications generally has a structure in which the p-type semiconductor layer is formed on the front surface side of the semiconductor device. An insulating film is formed on the front surface side of the semiconductor device to protect the surface of the semiconductor layer. The properties required of the insulating film include good step coverage on the semiconductor layer surface and dense film quality, and the like. A plasma chemical vapor deposition (Plasma CVD) method is commonly used as an insulating film deposition technique that can achieve above requirements.

Unfortunately, in a case where the plasma CVD method is used as the deposition method for insulating films to protect the surface of the semiconductor layers, hydrogen radicals generated during insulating film deposition cause hydrogen to be incorporated into the insulating film. The hydrogen incorporated into the insulating film may diffuse into the p-type semiconductor layer during annealing and other processes in the manufacturing process after the insulating film deposition. Furthermore, there is a possibility that hydrogen may diffuse into the p-type semiconductor layer depending on conditions such as storage, operation, and operating environment of the semiconductor device after completion of the semiconductor device.

Non-Patent Document 1 points out that hydrogen in the p-type semiconductor layer causes a decrease in carrier concentration. Since the decrease in the carrier concentration of the p-type semiconductor layer directly leads to an increase in the device resistance of the semiconductor device, there is a possibility that the device characteristics may vary depending on variations in conditions such as process, storage, operation, and operating environment. Furthermore, it is known that hydrogen in the semiconductor layer moves relatively easily, and in the worst case, there is a concern that hydrogen may affect long-term reliability of the semiconductor device. Non-Patent Document 2 describes that diffusion of hydrogen from the insulating film into the p-type semiconductor layer can be suppressed by providing an n-type semiconductor layer on the surface of the semiconductor layer.

The present disclosure has been made to solve the above problem, and an object of the present disclosure is to provide a semiconductor device which can operate with a broad frequency bandwidth and high light emission efficiency by suppressing diffusion of hydrogen from an insulating film into a p-type semiconductor layer and thus preventing an increase in device resistance of the semiconductor device.

### Solution to the Problems

A semiconductor device according to the present disclosure includes: a semiconductor substrate; stacked semiconductor layers formed on the semiconductor substrate and including a first-conductivity-type first semiconductor layer, an active layer, and a second-conductivity-type semiconductor layer; a first-conductivity-type second semiconductor layer formed on the stacked semiconductor layers; and an insulating film formed in contact with the first-conductivity-type second semiconductor layer.

A method for manufacturing a semiconductor device according to the present disclosure includes: a first crystal growth step of forming stacked semiconductor layers by sequentially crystal-growing a first-conductivity-type first semiconductor layer, an active layer, and a second-conductivity-type semiconductor layer on a semiconductor substrate; a mesa structure forming step of processing the stacked semiconductor layers into a stripe-shaped mesa structure; a second crystal growth step of crystal-growing a buried layer on both side surfaces of the mesa structure; a third crystal growth step of crystal-growing a semiconductor layer including a first-conductivity-type second semiconductor layer on the buried layer; an insulating film forming step of depositing an insulating film on the first-conductivity-type second semiconductor layer by a plasma CVD method; and an opening portion forming step of forming an opening portion in a portion of the insulating film facing a top surface of the mesa structure.

### Effect of the Invention

According to the semiconductor device of the present disclosure, since the n-type semiconductor layer is provided directly under the insulating film provided on the outermost surface of the semiconductor layers, the n-type semiconductor layer prevents diffusion of hydrogen contained in the insulating film, thus providing an effect of obtaining a semiconductor device that can operate with a broad frequency bandwidth and high light emission efficiency.

According to the method for manufacturing a semiconductor device of the present disclosure, since the n-type semiconductor layer is crystal-grown on the outermost surface of the semiconductor layers, and the insulating film in contact with the n-type semiconductor layer is deposited by a plasma CVD method, the n-type semiconductor layer prevents diffusion of hydrogen contained in the insulating film, thus providing an effect that a semiconductor device operable with a broad frequency bandwidth and high light emission efficiency can be easily manufactured.

### BRIEF DESCRIPTION OF THE DRAWINGS

FIG. 1 is a cross-sectional view showing a configuration of a semiconductor device according to Embodiment 1;

FIG. 2 is a cross-sectional view showing a configuration of a buried-type semiconductor laser to which the semiconductor device structure according to Embodiment 1 is applied;

FIG. 3 is a cross-sectional view showing a configuration of a semiconductor device according to Modification 1 of Embodiment 1;

FIG. 4 is a cross-sectional view showing a configuration of a buried-type semiconductor laser to which a semiconductor device structure according to Modification 1 of Embodiment 1 is applied;

FIG. 5 is a cross-sectional view showing a configuration of a semiconductor device according to Modification 2 of Embodiment 1;

FIG. 6 is a cross-sectional view showing another configuration of the semiconductor device according to Modification 2 of Embodiment 1;

FIG. 7 is a cross-sectional view showing a configuration of a buried-type semiconductor laser to which a semiconductor device structure according to Embodiment 2 is applied;

FIG. 8 is a cross-sectional view showing an example of a configuration of a semiconductor device to which a semiconductor device structure according to Embodiment 3 is applied;

FIG. 9 is a cross-sectional view showing an example of a configuration of a ridge-type semiconductor laser to which a semiconductor device structure according to Modification 1 of Embodiment 3 is applied;

FIG. 10 is a cross-sectional view showing an example of a configuration of a buried-type semiconductor laser to which a semiconductor device structure according to Modification 2 of Embodiment 3 is applied;

FIG. 11 is a cross-sectional view showing a configuration of a semiconductor device according to Embodiment 4;

FIG. 12 is a cross-sectional view showing a configuration of a buried-type semiconductor laser to which the semiconductor device structure according to Embodiment 4 is applied.

### DESCRIPTION OF EMBODIMENTS

### Embodiment 1

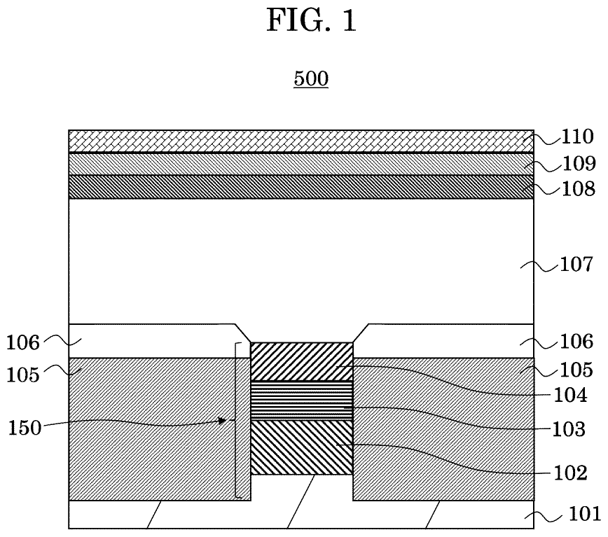

FIG. 1 is a cross-sectional view showing a configuration of a semiconductor device 500 according to Embodiment 1. FIG. 1 shows a buried-type semiconductor laser with an n-type InP (indium phosphide) substrate 101 and an AlGaInAs active layer 103 as an example of the semiconductor device 500 according to Embodiment 1.

### Configuration of Semiconductor Device According to Embodiment 1

The semiconductor device 500 includes: a mesa structure 150 composed of stripe-shaped stacked semiconductor layers having a S-doped n-type InP cladding layer (first-conductivity-type first semiconductor layer) 102, the undoped AlGaInAs active layer 103 sandwiched between AlGaInAs optical confinement layers on the top and bottom surfaces, and a Zn-doped p-type InP first cladding layer (second-conductivity-type semiconductor layer) 104, which are sequentially stacked on a (100) surface of the S-doped n-type InP substrate 101; a Fe-doped semi-insulating InP buried layer 105 and a S-doped n-type InP buried layer 106 formed on both side surfaces of the stripe-shaped mesa structure 150; a Zn-doped p-type InP second cladding layer (second-conductivity-type cladding layer) 107 formed so as to cover the top surface of the stripe-shaped mesa structure 150 and the surface of the S-doped n-type InP buried layer 106; a Zn-doped p-type InGaAs contact layer (second-conductivity-type contact layer) 108; a S-doped n-type InP barrier layer (first-conductivity-type second semiconductor layer) 109; and a SiO₂ insulating film 110 formed on the S-doped n-type InP barrier layer 109.

The semiconductor layers including the first-conductivity-type first semiconductor layer, the active layer, and the second-conductivity-type semiconductor layer are also referred to as stacked semiconductor layers.

Each semiconductor layer constituting the semiconductor device 500 is described below.

The doping concentration of the S-doped n-type InP substrate 101 is 5.0×10¹⁸ cm⁻³. The S-doped n-type InP cladding layer 102 has a thickness of 1.0 μm and a doping concentration of 1.0×10¹⁸ cm⁻³. The undoped AlGaInAs active layer 103 has a thickness of 0.3 μm. The Zn-doped p-type InP first cladding layer 104 has a thickness of 0.3 μm and a doping concentration of 1.0×10¹⁸ cm⁻³. The stripe-shaped mesa structure 150 has a height of 2.0 μm. The active layer made of undoped AlGaInAs is described as an example of the active layer, but the active layer may be made of a semiconductor layer containing Ga (gallium) and As (arsenic), and may be an n-type or a p-type semiconductor layer other than the undoped semiconductor layer.

The Fe-doped semi-insulating InP buried layer 105 has a thickness of 1.8 μm and a doping concentration of 5.0×10¹⁶ cm⁻³. The S-doped n-type InP buried layer 106 has a thickness of 0.2 μm and a doping concentration of 5.0×10¹⁸ cm⁻³.

### Method for Manufacturing Semiconductor Device According to Embodiment 1

A method for manufacturing the semiconductor device 500 according to Embodiment 1 will be described below.

The stacked semiconductor layers having the S-doped n-type InP cladding layer 102, the undoped AlGaInAs active layer 103 sandwiched between the AlGaInAs optical confinement layers on the top and bottom surfaces, and the Zn-doped p-type InP first cladding layer 104, are sequentially crystal-grown on the (100) surface of the S-doped n-type InP substrate 101 by a crystal growth method such as a metal organic chemical vapor deposition (MOCVD) method (first crystal growth step).

After the crystal growth of the above semiconductor layers, a stripe-shaped SiO₂ mask with a width of 1.5 μm in the <011> direction is formed on the surface of the Zn-doped p-type InP first cladding layer 104 by photolithography and etching.

Using the stripe-shaped SiO₂ mask as an etching mask, dry etching is performed from the Zn-doped p-type InP first cladding layer 104 to the S-doped n-type InP substrate 101, thereby forming the stripe-shaped mesa structure 150 having a height of 2.0 μm from the bottom surface (mesa structure forming step).

After the stripe-shaped mesa structure 150 is formed, the Fe-doped semi-insulating InP buried layer 105 and the S-doped n-type InP buried layer 106 are sequentially crystal-grown on both side surfaces of the stripe-shaped mesa structure 150 by the MOCVD method (second crystal growth step). The Fe-doped semi-insulating InP buried layer 105 and the S-doped n-type InP buried layer 106 function as current blocking layers during driving of the semiconductor device 500. After the formation of each buried layer, the SiO₂ mask is removed by wet etching using hydrofluoric acid as an etchant.

Then, the Zn-doped p-type InP second cladding layer 107, the Zn-doped p-type InGaAs contact layer 108, and the S-doped n-type InP barrier layer 109 are sequentially crystal-grown on the top surface of the stripe-shaped mesa structure 150 and the surface of the S-doped n-type InP buried layer 106 by the MOCVD method (third crystal growth step).

Then, the SiO₂ insulating film 110 is deposited over the entire surface by the plasma CVD method (insulating film forming step), and thus the semiconductor device 500 shown in FIG. 1 is completed. Note that the SiO₂ insulating film 110 deposited by the plasma CVD method is also referred to as a plasma CVD insulating film.

### First Effect of Embodiment 1

According to the semiconductor device of Embodiment 1, since the n-type InP barrier layer 109 is provided directly under the SiO₂ insulating film 110, the n-type InP barrier layer 109 prevents diffusion of the hydrogen contained in the SiO₂ insulating film 110, thus providing an effect of obtaining a semiconductor device that can operate with a broad frequency bandwidth and high light emission efficiency.

### Configuration of Buried-type Semiconductor Laser According to Embodiment 1

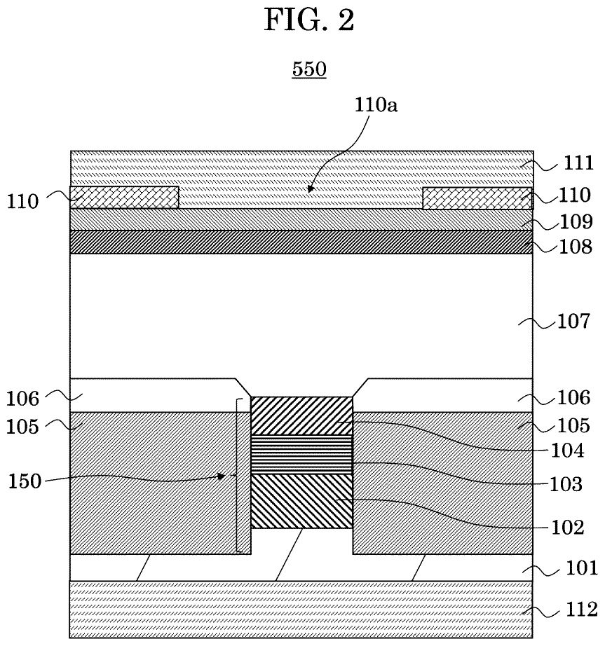

FIG. 2 is a cross-sectional view showing a configuration of a buried-type semiconductor laser 550 to which the semiconductor device 500 shown in FIG. 1 is applied. The device structure of the buried semiconductor laser 550 is based on the semiconductor device 500. The buried-type semiconductor laser 550 has the device structure in which an opening portion 110a is formed in the SiO₂ insulating film 110 of the semiconductor device 500, a front surface electrode 111 is provided on the SiO₂ insulating film 110 including the opening portion 110a, and a back surface electrode 112 is provided on the back surface side of the n-type InP substrate 101.

### Method for Manufacturing Buried-type Semiconductor Laser According to Embodiment 1

A method for manufacturing the buried-type semiconductor laser 550 according to Embodiment 1 is identical to the method for manufacturing the semiconductor device 500 up to the deposition of the SiO₂ insulating film 110 by the plasma CVD method, and therefore the subsequent manufacturing method will be described below.

After the SiO₂ insulating film 110 is deposited, the opening portion 110a having an opening width of 3 μm is formed in a portion of the SiO₂ insulating film 110 facing the top surface of the stripe-shaped mesa structure 150 by photolithography and dry etching (opening portion forming step).

The front surface electrode 111 is deposited on the SiO₂ insulating film 110 including the opening portion 110a. After the formation of the front surface electrode 111, the back surface is polished, and then the back surface electrode 112 is deposited on the back surface side of the n-type InP substrate 101 (electrode forming step), whereby the device structure as the buried-type semiconductor laser 550 shown in FIG. 2 is completed.

The InP layer and the InGaAs layer have n-type conductivity when doped with S, and have p-type conductivity when doped with Zn. In the device structure of the semiconductor device 500 and the buried-type semiconductor laser 550, the S-doped n-type InP barrier layer 109 exists between the SiO₂ insulating film 110 and the Zn-doped p-type InGaAs contact layer 108, and thus the S-doped n-type InP barrier layer 109 can suppress the diffusion of the hydrogen contained in the SiO₂ insulating film 110 into each semiconductor layer.

The example of the buried-type semiconductor laser 550 is described above. The same effect can be obtained by a ridge-type semiconductor laser described later.

In the above examples, sulfur(S) and zinc (Zn) are shown as dopants to the semiconductor layers, but the same effect can be obtained by using any kind of dopant as long as the type of dopant is an n-type or a p-type, respectively.

In the description of the above embodiment, the Fe-doped semi-insulating InP buried layer 105 and the S-doped n-type InP buried layer 106 are used to configure the current blocking layer, but other buried-type structures such as thyristor type or the like may be used.

### Second Effect of Embodiment 1

According to the buried-type semiconductor laser of Embodiment 1, since the n-type InP barrier layer 109 is provided directly under the SiO₂ insulating film 110, the n-type InP barrier layer 109 prevents the diffusion of the hydrogen contained in the SiO₂ insulating film 110, thus providing an effect of obtaining a buried-type semiconductor laser that can operate with a broad frequency bandwidth and high light emission efficiency.

### Modification 1 of Embodiment 1

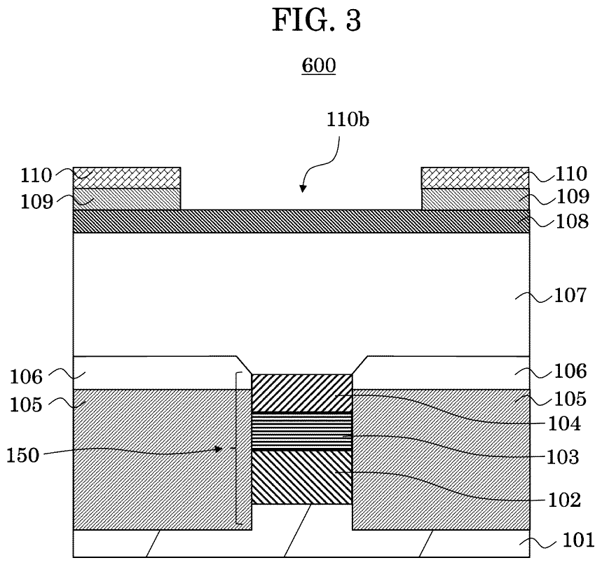

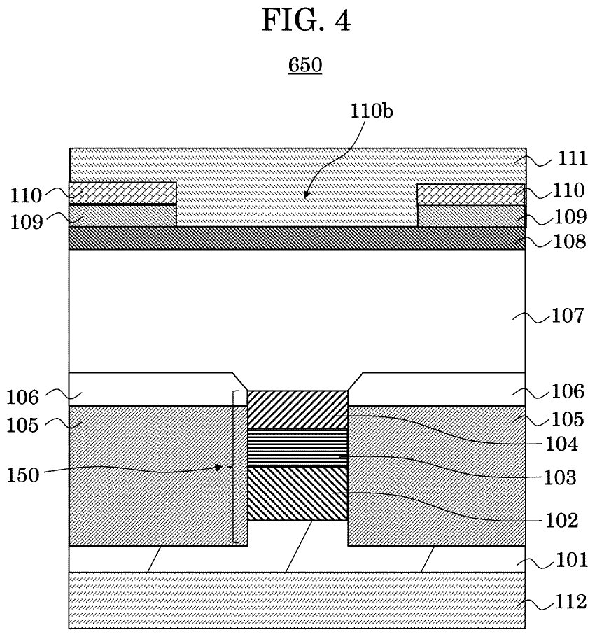

FIG. 3 is a cross-sectional view showing a configuration of a semiconductor device 600 according to Modification 1 of Embodiment 1. FIG. 4 is a cross-sectional view showing a configuration of a buried-type semiconductor laser 650 to which the semiconductor device structure according to Modification 1 of Embodiment 1 is applied.

### Configuration of Semiconductor Device According to Modification 1 of Embodiment 1

As shown in the cross-sectional view of FIG. 3, the semiconductor device 600 according to Modification 1 of Embodiment 1 has a configuration in which an opening portion 110b is provided in a portion of the n-type InP barrier layer (first-conductivity-type second semiconductor layer) 109 and the SiO₂ insulating film 110 facing the top surface of the stripe-shaped mesa structure 150 in the configuration of the semiconductor device 500 according to Embodiment 1.

The opening portion 110b has an opening width of 3 μm, and the p-type InGaAs contact layer 108 is exposed at the bottom of the opening portion 110b.

### Method for Manufacturing Semiconductor Device According to Modification 1 of Embodiment 1

The method for manufacturing the semiconductor device 600 according to Modification 1 of Embodiment 1 is identical to the method for manufacturing the buried-type semiconductor laser 550 up to the formation of the opening portion in the SiO₂ insulating film 110, and therefore the subsequent manufacturing method will be described below.

After forming the opening portion in the SiO₂ insulating film 110 on the surface of the semiconductor device, the S-doped n-type InP barrier layer 109 is etched using a chemical solution having etching selectivity to InGaAs until etching reaches the Zn-doped p-type InGaAs contact layer 108, thereby forming the opening portion 110b shown in FIG. 3. Since the chemical solution having etching selectivity is used, etching progresses in the S-doped n-type InP barrier layer 109, but stops at the surface of the Zn-doped p-type InGaAs contact layer 108. Consequently, the Zn-doped p-type InGaAs contact layer 108 is exposed at the bottom of the opening portion 110b.

### First Effect of Modification 1 of Embodiment 1

According to the semiconductor device of Modification 1 of Embodiment 1, since the n-type InP barrier layer 109 is provided directly under the SiO₂ insulating film 110, the n-type InP barrier layer 109 prevents diffusion of the hydrogen contained in the SiO₂ insulating film 110, thus providing an effect of obtaining a semiconductor device that can operate with a broad frequency bandwidth and high light emission efficiency.

### Configuration of Buried-type Semiconductor Laser According to Modification 1 of Embodiment 1

FIG. 4 is a cross-sectional view showing a configuration of a buried-type semiconductor laser 650 to which the semiconductor device structure according to Modification 1 of Embodiment 1 is applied. The buried-type semiconductor laser 650 has a device structure in which an opening portion 110b is formed in the SiO₂ insulating film 110 and the n-type InP barrier layer (first-conductivity-type second semiconductor layer) 109 of the semiconductor device 500, a front surface electrode 111 is provided on the SiO₂ insulating film 110 including the opening portion 110b, and a back surface electrode 112 is provided on the back surface side.

In the buried-type semiconductor laser 650, the n-type InP barrier layer 109 is inserted over the entire surface between the p-type InGaAs contact layer 108 and the SiO₂ insulating film 110, and thus the n-type InP barrier layer 109 can suppress the diffusion of the hydrogen contained in the SiO₂ insulating film 110 into each semiconductor layer.

In the buried-type semiconductor laser 650, the n-type InP barrier layer 109 between the front surface electrode 111 and the p-type InGaAs contact layer 108 is removed at the opening portion 110b of the SiO₂ insulating film 110, thus providing an effect that the contact resistance between the front surface electrode 111 and the semiconductor layer can be reduced.

### Second Effect of Modification 1 of Embodiment 1

According to the buried-type semiconductor laser of Modification 1 of Embodiment 1, since the n-type InP barrier layer 109 is provided directly under the SiO₂ insulating film 110, the n-type InP barrier layer 109 prevents the diffusion of the hydrogen contained in the SiO₂ insulating film 110, thus providing an effect of obtaining a buried-type semiconductor laser that can operate with a broad frequency bandwidth and high light emission efficiency.

### Modification 2 of Embodiment 1

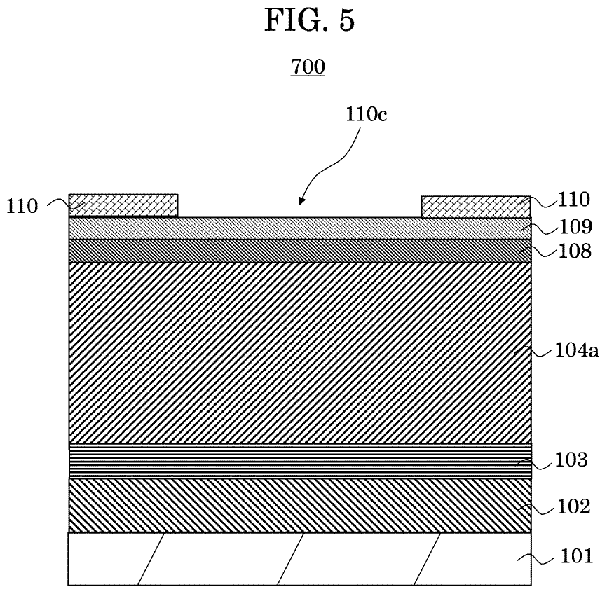

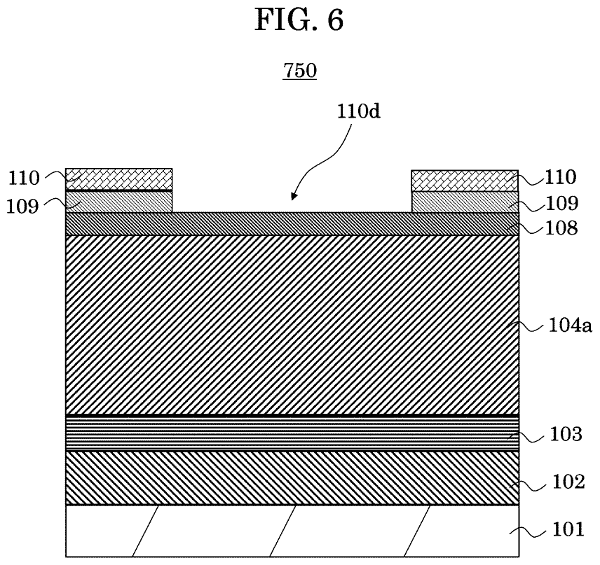

FIG. 5 is a cross-sectional view showing a configuration of a semiconductor device according to Modification 2 of Embodiment 1. FIG. 6 is a cross-sectional view showing another configuration of the semiconductor device according to Modification 2 of Embodiment 1.

### Configuration of Semiconductor Device According to Modification 2 of Embodiment 1

As shown in FIG. 5, the semiconductor device 700 according to Modification 2 of Embodiment 1 includes: semiconductor layers composed of a S-doped n-type InP cladding layer (first-conductivity-type first semiconductor layer) 102, an undoped AlGaInAs active layer 103 sandwiched between AlGaInAs optical confinement layers on the top and bottom surfaces, a Zn-doped p-type InP cladding layer (second-conductivity-type semiconductor layer) 104a, a Zn-doped p-type InGaAs contact layer 108, and a S-doped n-type InP barrier layer (first-conductivity-type second semiconductor layer) 109, which are sequentially stacked on a (100) surface of a S-doped n-type InP substrate 101; and a SiO₂ insulating film 110 formed on the S-doped n-type InP barrier layer 109 and provided with an opening portion 110c. The active layer made of undoped AlGaInAs is described as an example of the active layer, but the active layer may be made of a semiconductor layer containing Ga (gallium) and As (arsenic), and may be an n-type or a p-type semiconductor layer other than the undoped semiconductor layer.

### Other Configuration of Semiconductor Device According to Modification 2 of Embodiment 1

The semiconductor device 750 according to Modification 2 of Embodiment 1 has a configuration in which, in addition to the SiO₂ insulating film 110 of the semiconductor device 700, an opening portion 110d that reaches the n-type InP barrier layer (first-conductivity-type second semiconductor layer) 109 is provided.

### Effect of Modification 2 of Embodiment 1

According to the semiconductor device of Modification 2 of Embodiment 1, since the n-type InP barrier layer 109 is provided directly under the SiO₂ insulating film 110, the n-type InP barrier layer 109 prevents the diffusion of the hydrogen contained in the SiO₂ insulating film 110, thus providing an effect of obtaining a semiconductor device that can operate with a broad frequency bandwidth and high light emission efficiency.

### Embodiment 2

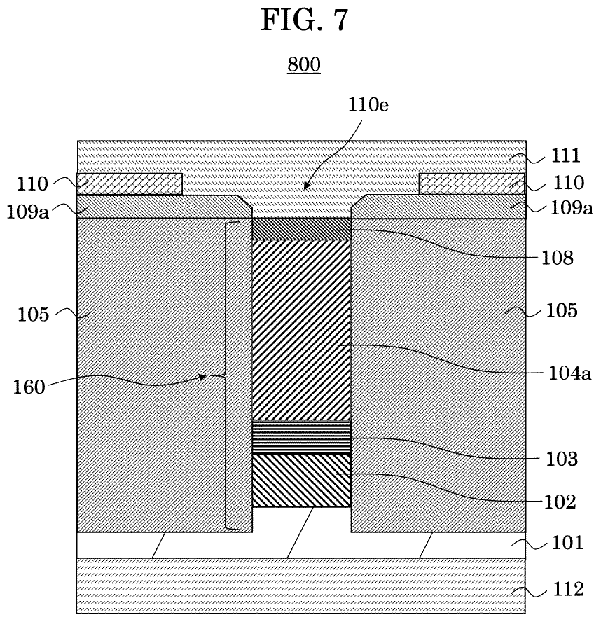

FIG. 7 is a cross-sectional view showing a configuration of a semiconductor device 800 according to Embodiment 2. FIG. 7 shows a buried-type semiconductor laser with an n-type InP substrate 101 and an AlGaInAs active layer 103 as an example of the semiconductor device 800 according to Embodiment 2, as in Embodiment 1.

### Configuration of Semiconductor Device According to Embodiment 2

The semiconductor device 800 includes: a mesa structure 160 composed of stripe-shaped stacked semiconductor layers having a S-doped n-type InP cladding layer (first-conductivity-type first semiconductor layer) 102, the undoped AlGaInAs active layer 103 sandwiched between AlGaInAs optical confinement layers on the top and bottom surfaces, a Zn-doped p-type InP cladding layer (second-conductivity-type semiconductor layer) 104a, and a Zn-doped p-type InGaAs contact layer 108, which are sequentially stacked on the (100) surface of a S-doped n-type InP substrate 101; semiconductor layers each composed of a Fe-doped semi-insulating InP buried layer 105 and a S-doped n-type InP buried-barrier layer (first-conductivity-type second semiconductor layer) 109a formed on both side surfaces of the stripe-shaped mesa structure 160; a SiO₂ insulating film 110 formed on the S-doped n-type InP buried-barrier layer 109a and provided with an opening portion 110e; a front surface electrode 111 provided on the SiO₂ insulating film 110 including the opening portion 110e; and a back surface electrode 112 provided on the back surface side of the S-doped n-type InP substrate 101.

Each semiconductor layer constituting the semiconductor device 800 is described below.

The doping concentration of the S-doped n-type InP substrate 101 is 5.0×10¹⁸ cm⁻³. The S-doped n-type InP cladding layer 102 has a thickness of 1.0 μm and a doping concentration of 1.0×10¹⁸ cm⁻³. The undoped AlGaInAs active layer 103 has a thickness of 0.3 μm. The Zn-doped p-type InP cladding layer 104a has a thickness of 2.3 μm and a doping concentration of 1.0×10¹⁸ cm⁻³. The Zn-doped p-type InGaAs contact layer 108 has a thickness of 0.3 μm and a doping concentration of 1.0×10¹⁹ cm⁻³. The active layer made of undoped AlGaInAs is described as an example of the active layer, but the active layer may be made of a semiconductor layer containing Ga (gallium) and As (arsenic), and may be an n-type or a p-type semiconductor layer other than the undoped semiconductor layer.

The Fe-doped semi-insulating InP buried layer 105 has a thickness of 4.0 μm and a doping concentration of 5.0×10¹⁶ cm⁻³. The S-doped n-type InP buried-barrier layer 109a has a thickness of 0.5 μm and a doping concentration of 5.0×10¹⁸ cm⁻³. The stripe-shaped mesa structure 160 has a height of 4.5 μm.

### Method for Manufacturing Semiconductor Device According to Embodiment 2

A method for manufacturing the semiconductor device 800 according to Embodiment 2 will be described below.

The stacked semiconductor layers having the S-doped n-type InP cladding layer 102, the undoped AlGaInAs active layer 103 sandwiched between the AlGaInAs optical confinement layers on the top and bottom surfaces, the Zn-doped p-type InP cladding layer 104a, and the Zn-doped p-type InGaAs contact layer 108 are sequentially crystal-grown on the (100) surface of the S-doped n-type InP substrate 101 by a crystal growth method such as the MOCVD method (first crystal growth step).

After the crystal growth of the above semiconductor layers, a stripe-shaped SiO₂ mask with a width of 1.5 μm in the <011> direction is formed on the surface of the Zn-doped p-type InGaAs contact layer 108 by photolithography and etching.

Using the stripe-shaped SiO₂ mask as an etching mask, dry etching is performed from the Zn-doped p-type InGaAs contact layer 108 to the S-doped n-type InP substrate 101, thereby forming the stripe-shaped mesa structure 160 having the height of 4.5 μm from the bottom surface (mesa structure forming step).

After the stripe-shaped mesa structure 160 is formed, the Fe-doped semi-insulating InP buried layer 105 and the S-doped n-type InP buried-barrier layer 109a are sequentially crystal-grown on both side surfaces of the stripe-shaped mesa structure 160 by the MOCVD method (second crystal growth step). The Fe-doped semi-insulating InP buried layer 105 and the S-doped n-type InP buried-barrier layer 109a function as current blocking layers during driving of the semiconductor device 800.

After the formation of each buried layer, the SiO₂ mask is removed by wet etching using hydrofluoric acid as an etchant. Then, the SiO₂ insulating film 110 is deposited over the entire surface by the plasma CVD method (insulating film forming step).

After the SiO₂ insulating film 110 is deposited, the opening portion 110e having an opening width of 3 μm is formed in a portion of the SiO₂ insulating film 110 facing the top surface of the stripe-shaped mesa structure 160 by photolithography and dry etching (opening portion forming step).

The front surface electrode 111 is deposited on the SiO₂ insulating film 110 including the opening portion 110a. After the formation of the front surface electrode 111, the back surface is polished, and then the back surface electrode 112 is deposited on the back surface side of the n-type InP substrate 101 (electrode forming step), whereby the device structure as the buried-type semiconductor laser shown in FIG. 7 is completed.

In the device structure of the semiconductor device 800, the n-type InP buried-barrier layer 109a exists between the SiO₂ insulating film 110 and the Fe-doped semi-insulating InP buried layer 105, and thus the n-type InP buried-barrier layer 109a can suppress the diffusion of the hydrogen contained in the SiO₂ insulating film 110 into each semiconductor layer.

### Effects of Embodiment 2

According to the semiconductor device of Embodiment 2, since the n-type InP buried-barrier layer 109a is provided directly under the SiO₂ insulating film 110, n-type InP buried-barrier layer 109a prevents the diffusion of the hydrogen contained in the SiO₂ insulating film 110, thus providing an effect of obtaining a semiconductor device that can operate with a broad frequency bandwidth and high light emission efficiency.

### Embodiment 3

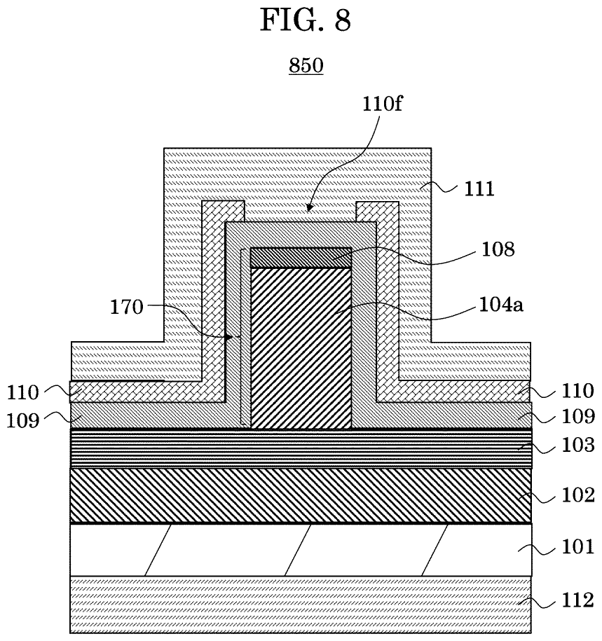

FIG. 8 is a cross-sectional view showing a configuration of a semiconductor device 850 according to Embodiment 3. FIG. 8 shows a ridge-type semiconductor laser with an n-type InP substrate 101 and an AlGaInAs active layer 103 as an example of the semiconductor device 850 according to Embodiment 2, as in Embodiment 1.

### Configuration of Semiconductor Device According to Embodiment 3

The semiconductor device 850 includes: a ridge structure 170 composed of stripe-shaped stacked semiconductor layers having a S-doped n-type InP cladding layer (first-conductivity-type first semiconductor layer) 102, the undoped AlGaInAs active layer 103 sandwiched between AlGaInAs optical confinement layers on the top and bottom surfaces, a Zn-doped p-type InP cladding layer (second-conductivity-type semiconductor layer) 104a, and a Zn-doped p-type InGaAs contact layer 108, which are sequentially stacked on a (100) surface of the S-doped n-type InP substrate 101; a S-doped n-type InP barrier layer (first-conductivity-type second semiconductor layer) 109 formed on both side surfaces of the stripe-shaped ridge structure 170; a SiO₂ insulating film 110 formed on the S-doped n-type InP barrier layer 109 and provided with an opening portion 110f; a front surface electrode 111 provided on the SiO₂ insulating film 110 including the opening portion 110f; and a back surface electrode 112 provided on the back surface side of the S-doped n-type InP substrate 101.

Each semiconductor layer constituting the semiconductor device 850 is described below.

The doping concentration of the S-doped n-type InP substrate 101 is 5.0×10¹⁸ cm⁻³. The S-doped n-type InP cladding layer 102 has a thickness of 1.0 μm and a doping concentration of 1.0×10¹⁸ cm⁻³. The undoped AlGaInAs active layer 103 has a thickness of 0.3 μm. The Zn-doped p-type InP cladding layer 104a has a thickness of 2.3 μm and a doping concentration of 1.0×10¹⁸ cm⁻³. The Zn-doped p-type InGaAs contact layer 108 has a thickness of 0.3 μm and a doping concentration of 1.0×10¹⁹ cm⁻³. The active layer made of undoped AlGaInAs is described as an example of the active layer, but the active layer may be made of a semiconductor layer containing Ga (gallium) and As (arsenic), and may be an n-type or a p-type semiconductor layer other than the undoped semiconductor layer.

The S-doped n-type InP barrier layer 109 has a thickness of 0.5 μm and a doping concentration of 1.0×10¹⁸ cm⁻³. The stripe-shaped ridge structure 170 has a height of 2.6 μm.

### Method for Manufacturing Semiconductor Device According to Embodiment 3

A method for manufacturing the semiconductor device 800 according to Embodiment 3 will be described below.

The stacked semiconductor layers having the S-doped n-type InP cladding layer 102, the undoped AlGaInAs active layer 103 sandwiched between the AlGaInAs optical confinement layers on the top and bottom surfaces, the Zn-doped p-type InP cladding layer 104a, and the Zn-doped p-type InGaAs contact layer 108 are sequentially crystal-grown on the (100) surface of the S-doped n-type InP substrate 101 by a crystal growth method such as the MOCVD method (first crystal growth step).

After the crystal growth of the above semiconductor layers, a stripe-shaped SiO₂ mask with a width of 1.5 μm in the <011> direction is formed on the surface of the Zn-doped p-type InGaAs contact layer 108 by photolithography and etching.

Using the stripe-shaped SiO₂ mask as an etching mask, the Zn-doped p-type InGaAs contact layer 108 and the Zn-doped p-type InP cladding layer 104a are dry-etched to be processed into a ridge shape, thereby forming the stripe-shaped ridge structure 170 having the height of 2.6 μm from the bottom surface (mesa structure forming step).

After the stripe-shaped ridge structure 170 is formed, the S-doped n-type InP barrier layer 109 is crystal-grown on the stripe-shaped ridge structure 170 by the MOCVD method (second crystal growth step).

After the formation of each buried layer, the SiO₂ mask is removed by wet etching using hydrofluoric acid as an etchant. Then, the SiO₂ insulating film 110 is deposited over the entire surface by the plasma CVD method (insulating film forming step).

After the SiO₂ insulating film 110 is deposited, the opening portion 110f having an opening width of 3 μm is formed in a portion of the SiO₂ insulating film 110 on the top surface of the stripe-shaped ridge structure 170 by photolithography and dry etching (opening portion forming step).

The front surface electrode 111 is deposited on the SiO₂ insulating film 110 including the opening portion 110f. After the formation of the front surface electrode 111, the back surface is polished, and then the back surface electrode 112 is deposited on the back surface side of the S-doped n-type InP substrate 101 (electrode forming step), whereby the device structure as the ridge-type semiconductor laser shown in FIG. 8 is completed.

In the device structure of the semiconductor device 850, the n-type InP barrier layer 109 is inserted over the entire surface between the undoped AlGaInAs active layer 103 and the SiO₂ insulating film 110, and thus the n-type InP barrier layer 109 can suppress the diffusion of the hydrogen contained in the SiO₂ insulating film 110 into each semiconductor layer.

### Effects of Embodiment 3

According to the semiconductor device of Embodiment 3, since the n-type InP barrier layer 109 is provided directly under the SiO₂ insulating film 110, the n-type InP barrier layer 109 prevents the diffusion of the hydrogen contained in the SiO₂ insulating film 110, thus providing an effect of obtaining a semiconductor device that can operate with a broad frequency bandwidth and high light emission efficiency.

### Modification 1 of Embodiment 3

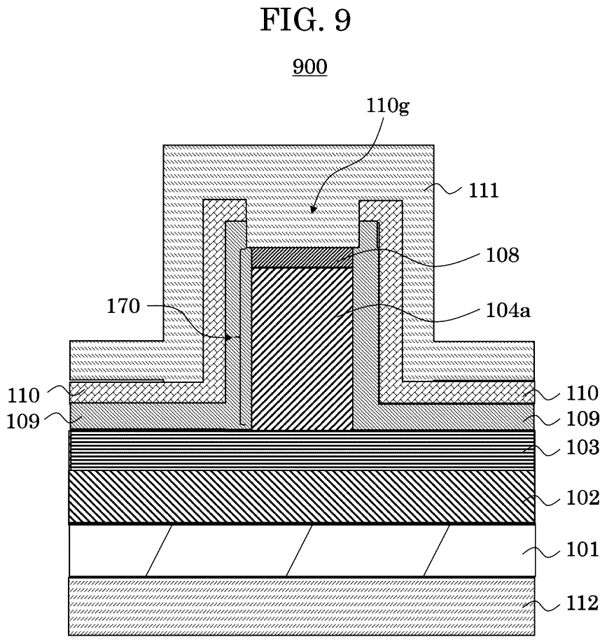

FIG. 9 is a cross-sectional view showing a configuration of a ridge-type semiconductor laser 900 to which the semiconductor device structure according to Embodiment 3 is applied. The ridge-type semiconductor laser 900 has the device structure in which an opening portion 110g is formed in a portion of the SiO₂ insulating film 110 and on the n-type InP barrier layer 109 on the top surface of the ridge structure 170, a front surface electrode 111 is provided on the SiO₂ insulating film 110 including the opening portion 110g, and a back surface electrode 112 is provided on the back surface side of the n-type InP substrate 101.

In the device structure of the ridge-type semiconductor laser 900, the n-type InP barrier layer 109 is inserted between the SiO₂ insulating film 110 and a part of each of the undoped AlGaInAs active layer 103, the p-type InGaAs contact layer 108, and the Zn-doped p-type InP cladding layer 104a, and thus the n-type InP barrier layer 109 can suppress the diffusion of the hydrogen contained in the SiO₂ insulating film 110 into each semiconductor layer.

In the ridge-type semiconductor laser 900, the n-type InP barrier layer 109 is removed between the front surface electrode 111 and the p-type InGaAs contact layer 108, thus providing an effect that the contact resistance between the front surface electrode 111 and the semiconductor layer can be reduced.

### Effects of Modification 1 of Embodiment 3

According to the semiconductor device of Modification 1 of Embodiment 3, since the n-type InP barrier layer 109 is provided directly under the SiO₂ insulating film 110, the n-type InP barrier layer 109 prevents the diffusion of the hydrogen contained in the SiO₂ insulating film 110 and the contact resistance between the front surface electrode 111 and the semiconductor layer can also be reduced, thus providing an effect of obtaining a ridge-type semiconductor laser that can operate with a broader frequency bandwidth and high light emission efficiency.

### Modification 2 of Embodiment 3

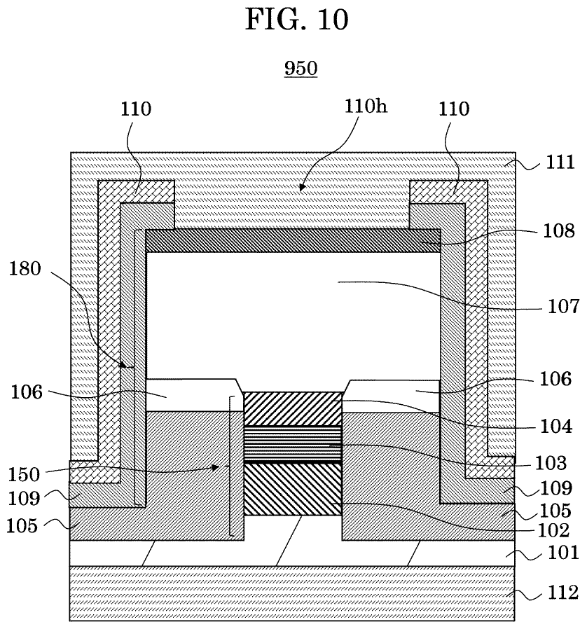

FIG. 10 is a cross-sectional view showing a configuration of a buried-type semiconductor laser 950 to which a semiconductor device structure according to Embodiment 3 is applied. The buried-type semiconductor laser 950 has the device structure in which the mesa structure 150 of the buried-type semiconductor laser 550 according to the Embodiment 1 is further processed into a mesa-shaped structure 180.

The buried-type semiconductor laser 950 has the device structure in which an opening portion 110h is formed in the SiO₂ insulating film 110 and the n-type InP barrier layer 109 on the top surface of the mesa-shaped structure 180, a front surface electrode 111 is provided on the SiO₂ insulating film 110 including the opening portion 110h, and a back surface electrode 112 is provided on the back surface side.

In the device structure of the buried-type semiconductor laser 950, the n-type InP barrier layer (first-conductivity-type second semiconductor layer) 109 is inserted between the SiO₂ insulating film 110 and a part of each of the semi-insulating InP buried layer 105, the n-type InP buried layer 106, the p-type InP second cladding layer 107, and the p-type InGaAs contact layer 108, and thus the n-type InP barrier layer 109 can suppress the diffusion of the hydrogen contained in the SiO₂ insulating film 110 into each semiconductor layer.

In addition, in the buried-type semiconductor laser 950, the n-type InP barrier layer 109 is removed between the front surface electrode 111 and the p-type InGaAs contact layer 108, thus providing an effect that the contact resistance between the front surface electrode 111 and the semiconductor layer can be reduced.

### Effects of Modification 2 of Embodiment 3

According to the semiconductor device of Modification 2 of Embodiment 3, since the n-type InP barrier layer 109 is provided directly under the SiO₂ insulating film 110, the n-type InP barrier layer 109 prevents the diffusion of the hydrogen contained in the SiO₂ insulating film 110 and the contact resistance between the front surface electrode 111 and the semiconductor layer can also be reduced, thus providing an effect of obtaining a buried-type semiconductor laser that can operate with a broad frequency bandwidth and high light emission efficiency.

### Embodiment 4

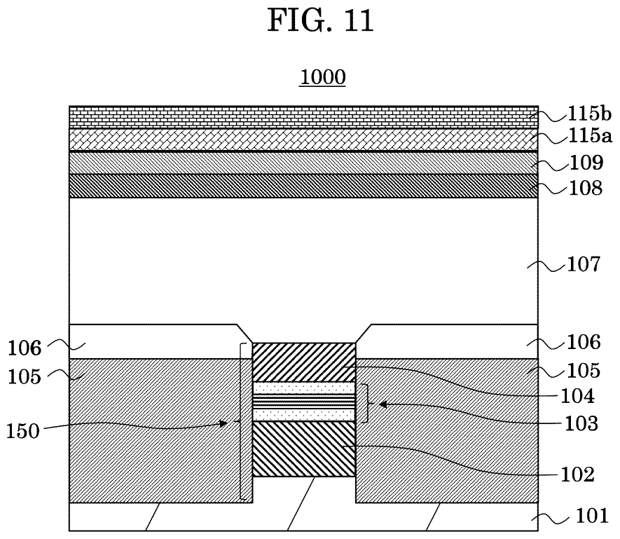

FIG. 11 is a cross-sectional view showing a configuration of a semiconductor device 1000 according to Embodiment 4. FIG. 11 shows a buried-type semiconductor laser with an n-type InP substrate 101 and an AlGaInAs active layer 103 as an example of a semiconductor device 1000 according to Embodiment 1.

### Configuration of Semiconductor Device According to Embodiment 4

The semiconductor device 1000 includes: a mesa structure 150 composed of stripe-shaped stacked semiconductor layers having a S-doped n-type InP cladding layer (first-conductivity-type first semiconductor layer) 102, the undoped AlGaInAs active layer 103 sandwiched between AlGaInAs optical confinement layers on the top and bottom surfaces, and a Zn-doped p-type InP first cladding layer (second-conductivity-type semiconductor layer) 104, which are sequentially stacked on the (100) surface of a S-doped n-type InP substrate 101; a Fe-doped semi-insulating InP buried layer 105 and a S-doped n-type InP buried layer 106 formed on both side surfaces of the stripe-shaped mesa structure 150; a Zn-doped p-type InP second cladding layer (second-conductivity-type cladding layer) 107 formed so as to cover the top surface of the stripe-shaped mesa structure 150 and the surface of the S-doped n-type InP buried layer 106; a Zn-doped p-type InGaAs contact layer (second-conductivity-type contact layer) 108; a S-doped n-type InP barrier layer (first-conductivity-type second semiconductor layer) 109; and a SiO₂ insulating film including two layers of a SiO₂ first insulating film 115a and a SiO₂ second insulating film 115b formed on the S-doped n-type InP barrier layer 109.

Each semiconductor layer constituting the semiconductor device 1000 is described below.

The doping concentration of the S-doped n-type InP substrate 101 is 5.0×10¹⁸ cm⁻³. The S-doped n-type InP cladding layer 102 has a thickness of 1.0 μm and a doping concentration of 1.0×10¹⁸ cm⁻³. The undoped AlGaInAs active layer 103 has a thickness of 0.3 μm. The Zn-doped p-type InP first cladding layer 104 has a thickness of 0.3 μm and a doping concentration of 1.0×10¹⁸ cm⁻³. The stripe-shaped mesa structure 150 has a height of 2.0 μm. The active layer made of undoped AlGaInAs is described as an example of the active layer, but the active layer may be made of a semiconductor layer containing Ga (gallium) and As (arsenic), and may be an n-type or a p-type semiconductor layer other than the undoped semiconductor layer.

The Fe-doped semi-insulating InP buried layer 105 has a layer thickness of 1.8 μm and a doping concentration of 5.0×10¹⁶ cm⁻³. The S-doped n-type InP buried layer 106 has a thickness of 0.2 μm and a doping concentration of 5.0×10¹⁸ cm⁻³.

The Zn-doped p-type InP second cladding layer 107 has a thickness of 2.0 μm and a doping concentration of 1.0×10¹⁸ cm⁻³. The Zn-doped p-type InGaAs contact layer 108 has a thickness of 0.3 μm and a doping concentration of 1.0×10¹⁹ cm⁻³. The S-doped n-type InP barrier layer 109 has a thickness of 0.2 μm and a doping concentration of 1.0×10¹⁸ cm⁻³.

### Method for Manufacturing Semiconductor Device According to Embodiment 4

The difference between the method for manufacturing a semiconductor device according to Embodiment 4 and the method for manufacturing a semiconductor device according to Embodiment 1 is only the step of forming the SiO₂ insulating film including two layers of the SiO₂ first insulating film 115a and the SiO₂ second insulating film 115b, and therefore, the formation of the SiO₂ insulating film will be described below.

The SiO₂ first insulating film 115a is deposited over the entire surface of the S-doped n-type InP barrier layer 109 by a sputtering method, and then the SiO₂ second insulating film 115b is deposited over the SiO₂ first insulating film 115a by a plasma CVD method (insulating film forming step), thereby completing the structure of the semiconductor device 1000 shown in FIG. 11.

Since hydrogen contamination does not occur in the SiO₂ first insulating film 115a formed by the sputtering method, the influence of diffusion of the hydrogen from the SiO₂ second insulating film 115b formed by the plasma CVD method can be suppressed. Therefore, the thickness of the n-type InP barrier layer 109 on the semiconductor layer surface can be reduced. Note that Non-Patent Document 2 points out that the prevention of hydrogen diffusion is less effective in a case where a thickness of an n-type InP layer is thin.

### Effects of Semiconductor Device According to Embodiment 4

According to the semiconductor device of Embodiment 4, since the SiO₂ insulating film is composed of two layers of the SiO₂ first insulating film 115a and the SiO₂ second insulating film 115b, a thickness of the n-type InP barrier layer 109 provided directly under the SiO₂ insulating film can be reduced, thus providing an effect of obtaining a semiconductor device that can operate with a broad frequency bandwidth and high light emission efficiency.

### Configuration of Buried-type Semiconductor Laser According to Embodiment 4

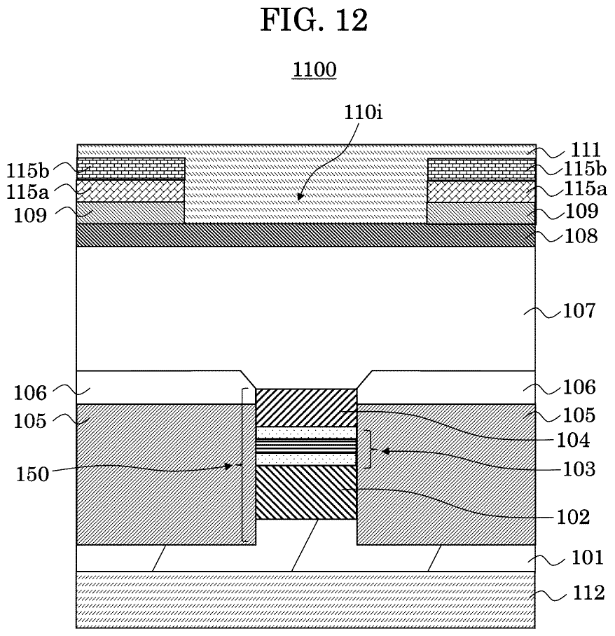

FIG. 12 is a cross-sectional view showing a configuration of a buried-type semiconductor laser 1100 to which the semiconductor device structure according to Embodiment 4 is applied. The buried-type semiconductor laser 1100 has the device structure in which an opening portion 110i is formed in a portion of the n-type InP barrier layer 109, the SiO₂ first insulating film 115a and the SiO₂ second insulating film 115b which are facing the top surface of the mesa structure 150 in the configuration of the semiconductor device 1000, a front surface electrode 111 is provided on the SiO₂ second insulating film 115b including the opening portion 110i, and a back surface electrode 112 is provided on the back surface side of the n-type InP substrate 101.

The opening portion 110i of the buried-type semiconductor laser 1100 is formed by first forming 3 μm wide opening portion in the SiO₂ first insulating film 115a and the SiO₂ second insulating film 115b facing the top of the mesa structure 150 by photolithography and dry etching, and then etching the n-type InP barrier layer 109 with a chemical solution having etching selectivity to InGaAs.

Since hydrogen contamination does not occur in the SiO₂ first insulating film 115a deposited by the sputtering method, the influence of diffusion of the hydrogen from the SiO₂ second insulating film 115b deposited by the plasma CVD method can be suppressed. Therefore, the thickness of the n-type InP barrier layer 109 on the semiconductor layer surface can be reduced.

### Effects of Buried-type Semiconductor Laser According to Embodiment 4

According to the buried-type semiconductor laser of Embodiment 4, since the SiO₂ insulating film is composed of two layers of the SiO₂ first insulating film 115a and the SiO₂ second insulating film 115b, the thickness of the n-type InP barrier layer 109 provided directly under the SiO₂ insulating film 110 can be reduced, thus providing an effect of obtaining a buried-type semiconductor laser that can operate with a broad frequency bandwidth and high light emission efficiency.

In Embodiment 4, it is explained that the SiO₂ insulating film is composed of two layers of the SiO₂ first insulating film 115a and the SiO₂ second insulating film 115b. Such SiO₂ insulating film composed of two layers may be applied to the semiconductor device or the semiconductor laser according to Embodiments 1 to 3.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

101 n-type InP substrate
102 n-type InP cladding layer
103 undoped AlGaInAs active layer
104 p-type InP first cladding layer
104a p-type InP cladding layer
105 semi-insulating InP buried layer
106 n-type InP buried layer
107 p-type InP second cladding layer
108 p-type InGaAs contact layer
109 n-type InP barrier layer
109a n-type InP buried-barrier layer
110 SiO₂ insulating film
110a, 110b, 110c, 110d, 110e, 110f, 110g, 110i opening portion
115a SiO₂ first insulating film
115b SiO₂ second insulating film
150, 160 mesa structure
170 ridge structure
180 mesa-shaped structure
500, 600, 700, 750, 800, 850, 1000 semiconductor device
550, 650, 950, 1100 buried-type semiconductor laser
900 ridge-type semiconductor laser

1. A semiconductor device comprising:
a semiconductor substrate;
stacked semiconductor layers formed on the semiconductor substrate and including a first-conductivity-type first semiconductor layer, an active layer, and a second-conductivity-type semiconductor layer;
a first-conductivity-type second semiconductor layer formed on the stacked semiconductor layers; and
an insulating film formed in contact with the first-conductivity-type second semiconductor layer.

2. The semiconductor device according to claim 1, wherein
an opening portion is provided in the insulating film, and the first-conductivity-type second semiconductor layer is exposed at a bottom of the opening portion.

3. A semiconductor device comprising:
a semiconductor substrate;
a mesa structure composed of stacked semiconductor layers formed on the semiconductor substrate and including a first-conductivity-type first semiconductor layer, an active layer, and a second-conductivity-type semiconductor layer, the stacked semiconductor layers being formed in a stripe shape;
a buried layer buried on both side surfaces of the mesa structure;
a first-conductivity-type second semiconductor layer formed on the buried layer; and
an insulating film formed in contact with the first-conductivity-type second semiconductor layer.

4. The semiconductor device according to claim 3, further comprising:
a first-conductivity-type second semiconductor layer formed on an upper surface of the mesa structure.

5. The semiconductor device according to claim 4, wherein
an opening portion is provided in a portion of the insulating film facing a top surface of the mesa structure, and the first-conductivity-type second semiconductor layer is exposed at a bottom of the opening portion.

6. The semiconductor device according to claim 4, wherein
an opening portion is provided in a portion of the insulating film and the first-conductivity-type second semiconductor layer facing a top surface of the mesa structure.

7. The semiconductor device according to claim 6, wherein
a region including the mesa structure and the buried layer further has a mesa shape.

8. The semiconductor device according to claim 3, further comprising:
a second-conductivity-type cladding layer and a second-conductivity-type contact layer formed between the second-conductivity-type semiconductor layer and the first-conductivity-type second semiconductor layer.

9. A semiconductor device comprising:
a semiconductor substrate;
a ridge structure including a first-conductivity-type first semiconductor layer, an active layer and at least a second-conductivity-type semiconductor layer on the active layer, which are formed sequentially on the semiconductor substrate in a stripe-shape;
a first-conductivity-type second semiconductor layer formed so as to cover the ridge structure; and
an insulating film formed in contact with the first-conductivity-type second semiconductor layer.

10. The semiconductor device according to claim 9, wherein
an opening portion is provided in a portion of the insulating film on the upper surface side of the ridge structure.

11. The semiconductor device according to claim 9, wherein
an opening portion is provided in a portion of the insulating film and the first-conductivity-type second semiconductor layer on the upper surface side of the ridge structure.

12. The semiconductor device according to claim 1, wherein
the insulating film is composed of a first insulating film and a second insulating film, and the first insulating film is formed of a plasma CVD insulating film.

13. The semiconductor device according to claim 1, wherein
the semiconductor substrate, the first-conductivity-type first semiconductor layer, and the second-conductivity-type semiconductor layer are composed of indium phosphide, and the active layer is composed of a semiconductor layer containing gallium and arsenic.

14. The semiconductor device according to claim 1, wherein
the first conductivity type is an n-type, and the second conductivity type is a p-type.

15. A method for manufacturing a semiconductor device, comprising:
a first crystal growth step of forming stacked semiconductor layers by sequentially crystal-growing a first-conductivity-type first semiconductor layer, an active layer, and a second-conductivity-type semiconductor layer on a semiconductor substrate;
a mesa structure forming step of processing the stacked semiconductor layers into a stripe-shaped mesa structure;
a second crystal growth step of crystal-growing a buried layer on both side surfaces of the mesa structure;
a third crystal growth step of crystal-growing a semiconductor layer including a first-conductivity-type second semiconductor layer on the buried layer;
an insulating film forming step of depositing an insulating film on the first-conductivity-type second semiconductor layer by a plasma CVD method; and
an opening portion forming step of forming an opening portion in a portion of the insulating film facing a top surface of the mesa structure.

16. The method for manufacturing a semiconductor device according to claim 15, wherein
in the opening portion forming step, the opening portion is provided in a portion of the insulating film and the first-conductivity-type second semiconductor layer facing the top surface of the mesa structure.

17. The method for manufacturing a semiconductor device according to claim 15, wherein
the insulating film is composed of two layers of a first insulating film in contact with the first-conductivity-type second semiconductor layer and a second insulating film on the first insulating film, and
in the insulating film forming step, the first insulating film is deposited by a sputtering method, and the second insulating film is deposited by the plasma CVD method.

18. The semiconductor device according to claim 3, wherein
the insulating film is composed of a first insulating film and a second insulating film, and the first insulating film is formed of a plasma CVD insulating film.

19. The semiconductor device according to claim 3, wherein
the semiconductor substrate, the first-conductivity-type first semiconductor layer, and the second-conductivity-type semiconductor layer are composed of indium phosphide, and the active layer is composed of a semiconductor layer containing gallium and arsenic.

20. The semiconductor device according to claim 3, wherein
the first conductivity type is an n-type, and the second conductivity type is a p-type.
